(19) United States
(12) Patent Application Publication
(10) Pub. No.: US 2023/0370026 A1
(43) Pub. Date: Nov. 16, 2023

(54) MULTI-MODE POWER AMPLIFIER SYSTEM WITH ADJUSTABLE POWER AMPLIFIER AND OUTPUT MATCHING NETWORK

(71) Applicant: Skyworks Solutions, Inc., Irvine, CA (US)

(72) Inventors: Neal J. Tuffy, Great Shelford (GB); Valter Karavanic, Nashua, NH (US); Martin John O’Flaherty, Bishop’s Stortford (GB); Michael John Ball, Newmarket (GB); Alasdair Bruce, Bishop’s Stortford (GB)

(21) Appl. No.: 18/195,153

(22) Filed: May 9, 2023

Related U.S. Application Data
(60) Provisional application No. 63/364,523, filed on May 11, 2022.
(60) Provisional application No. 63/364,530, filed on May 11, 2022.
(60) Provisional application No. 63/364,546, filed on May 11, 2022.

(51) Int. Cl. H03F 3/24; H04B 1/04; H04B 1/401; H03F 3/19; H03F 1/56

(52) U.S. Cl. CPC H03F 3/245; H04B 1/0458; H04B 1/401; H03F 3/19; H03F 1/565; H04B 2001/045; H03F 2200/451; H03F 2203/21109

(57) ABSTRACT

Multi-mode power amplifier systems are described. In certain embodiments, a multi-mode power amplifier system shares a power amplifier chain for different communication modes, where the power amplifier chain has a split output matching network with a first power amplifier transistor and a second power amplifier transistor. A bias circuit biases the power amplifier such that the first power amplifier transistor and the second power amplifier transistor are on in a first mode, and the first power amplifier transistor is on and the second power amplifier transistor is off in a second mode.

### INCORPORATION BY REFERENCE TO ANY PRIORITY APPLICATIONS

Any and all applications, if any, for which a foreign or domestic priority claim is identified in the Application Data Sheet of the present application are hereby incorporated by reference under 37 CFR 1.57.

### BACKGROUND

### Technical Field

Embodiments of this disclosure relate to multi-mode power amplifiers.

### Description of Related Technology

Radio frequency (RF) communication systems can be used for transmitting and/or receiving signals with a wide range of frequencies. For example, an RF communication system can be used to wirelessly communicate RF signals in a frequency range of about 30 kilohertz (kHz) to 300 gigahertz (GHz), such as in the range of about 400 megahertz (MHz) to about 6 GHz.

Examples of RF communication systems include, but are not limited to, mobile phones, tablets, base stations, network access points, customer-premises equipment (CPE), laptops, and wearable electronics.

In certain applications, RF communications systems can transmit different signals in different modes. Radio frequency power amplifiers can be used in amplifying such RF signals for transmission.

### SUMMARY

For purposes of summarizing the invention, certain aspects, advantages and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

In certain embodiments, the present disclosure describes multi-mode power amplifier systems that share a power amplifier chain for different communication modes. In one or more embodiments the power amplifier chain is configured for different modes with a split output matching network. In certain embodiments, registers enhance and/or optimize bias settings in a plurality of modes and also include addition features to preserve high performance and to meet technical specifications in each of the modes.

For example, one multi-mode power amplifier system comprises a power amplifier including a first power amplifier transistor and a second power amplifier transistor, the power amplifier configured to amplify a radio frequency signal; a bias circuit biases the power amplifier such that (i) the first power amplifier transistor and the second power amplifier transistor are on in a first mode and (ii) the first power amplifier transistor is on and the second power amplifier transistor is off in a second mode; and an output matching network is coupled to an output of the power amplifier, the output matching network configured to adjust an output matching impedance for the power amplifier for the second mode relative to the first mode.

In another embodiment, of the multi-mode power amplifier system, the first mode is a wireless local area network mode and the second mode is a wireless personal area network mode. In yet another embodiment, the first mode a Wi Fi mode and the second mode is a Bluetooth mode.

In various embodiments, the output matching network includes a switch configured to adjust the output matching impedance for the power amplifier for the second mode relative to the first mode. In another embodiment, the power amplifier is on a silicon germanium die and the switch is on a silicon-on-insulator die. In yet another embodiment, the switch is configured to include a capacitor in the output matching impedance in the first mode and to not include the capacitor in the output matching impedance in the second mode. In a further embodiment, the capacitor is a shunt capacitor and the output matching network includes a series inductor. In an additional embodiment, the series inductor is a surface mount inductor.

In accordance with another embodiment, the output matching network includes a first section and a second section coupled to the output of the power amplifier by way of the first section, the second section including the switch, the series inductor, and the shunt capacitor.

In accordance with other embodiments, the power amplifier includes a gain stage and an output stage, the output stage including the first power amplifier transistor and the second power amplifier transistor. In yet another embodiment, the gain stage includes a third power amplifier transistor and a fourth power amplifier transistor, and the bias circuit is configured to bias the gain stage such that (i) the third power amplifier transistor and the fourth power amplifier transistor are on in the first mode and (ii) the third power amplifier transistor is on and the fourth power amplifier transistor is off in the second mode.

According to various embodiments, the bias circuit is configured to provide a reference current to the first power amplifier transistor, the reference current being different in the first mode than in the second mode. In another embodiment, the bias circuit includes memory elements that store reference current settings for at least the first mode and the second mode.

In accordance with a number of embodiments, a multi-chip module with a multi-mode power amplifier system comprises a power amplifier on a compound semiconductor die, the power amplifier including a first power amplifier transistor and a second power amplifier transistor; a bias circuit on the compound semiconductor die, the bias circuit configured to bias the power amplifier such that (i) the first power amplifier transistor and the second power amplifier transistor are on in a first mode and (ii) the first power amplifier transistor is on and the second power amplifier transistor is off in the second mode; and an output matching network implemented at least partly on a semiconductor on-insulator die, the output matching network configured to adjust an output matching impedance for the power amplifier for the second mode relative to the first mode, and the compound semiconductor die and the semiconductor on insulator die being on a common substrate and packaged together with each other.

In other embodiments, the compound semiconductor die is a silicon germanium die and the semiconductor-on-insulator die is a silicon-on-insulator die.

According to various embodiments, a wireless communication device with a multi-mode power amplifier system comprises a multi-mode power amplifier system including a power amplifier with a first power amplifier transistor and a second power amplifier transistor, the power amplifier configured to amplify a radio frequency signal, a bias circuit configured to bias the power amplifier such that (i) the first power amplifier transistor and the second power amplifier transistor are on in a first mode and (ii) the first power amplifier transistor is on and the second power amplifier transistor is off in a second mode, and an output matching network coupled to an output of the power amplifier, the output matching network configured to adjust an output matching impedance for the power amplifier for the second mode relative to the first mode; and an antenna operatively coupled to the power amplifier by way of at least the output matching network in both the first and second modes of operation. In other embodiments, multi-mode power amplifier system includes a baseband processor configured to provide a mode select signal to the bias circuit.

In certain embodiments, the present disclosure relates to methods of operating a multi-mode power amplifier system. In one embodiment, the method comprises amplifying a radio frequency signal in a first mode with a first power amplifier transistor of a power amplifier and a second power amplifier transistor of the power amplifier; adjusting a power amplifier signal path by deactivating the second power amplifier transistor and adjusting an output matching impedance for the power amplifier; and after said adjusting, amplifying the radio frequency signal in a second mode with the first power amplifier transistor while the second power amplifier transistor is deactivated, the output matching impedance being different for the second mode than for the first mode.

According to various embodiments, a multi-mode power amplifier system comprises at least one power amplifier configured to amplify a radio frequency signal in at least a first mode and a second mode; an output matching network coupled to an output of the at least one power amplifier; and a bias circuit configured to provide a reference current with a first reference current level to the at least one power amplifier in the first mode and a second reference current level to the at least one power amplifier in the second mode, the multi-mode power amplifier system configured to adjust a power amplifier signal path for the second mode relative to the first mode.

In one embodiment, the first mode is a wireless local area network mode and the second mode is a wireless personal area network mode. In other embodiments, the first mode is a Wi Fi mode and the second mode is a Bluetooth mode.

In one or more embodiments, the power amplifier signal path is adjusted by the bias circuit deactivating an auxiliary power amplifier transistor of the at least one power amplifier for the second mode, the auxiliary power amplifier transistor being activated for the first mode. In yet another embodiment, at least one power amplifier includes a gain stage and an output stage, the output stage including the auxiliary power amplifier transistor and a main power amplifier transistor, the gain stage including a second auxiliary power amplifier transistor and a second main power amplifier transistor, the bias circuit configured to deactivate the second auxiliary power amplifier transistor for the second mode. In a further embodiment, the power amplifier signal path is adjusted by adjusting an output matching impedance of the output matching network.

In certain embodiments, the power amplifier signal path is adjusted by adjusting an output matching impedance of the output matching network. In another embodiment, the output matching network includes a switch configured to include a capacitor in the output matching impedance in the first mode and to not include the capacitor in the output matching impedance in the second mode. In yet another embodiment, the capacitor is a shunt capacitor and the output matching network includes a series inductor.

In a further embodiment, the series inductor is a surface mount inductor. In an additional embodiment, the output matching network includes a first section and a second section coupled to the output of the at least one power amplifier by way of the first section, the second section including the switch and the capacitor. In another embodiment, the at least one power amplifier is on a silicon germanium die and the switch is on a silicon-on-insulator die. In yet another embodiment, a low noise amplifier is on a semiconductor-on-insulator die.

In various emboidiments, a multi-chip module with a multi-mode power amplifier system comprises: at least one power amplifier on a compound semiconductor die, the at least one power amplifier configured to amplify a radio frequency signal in at least a first mode and a second mode; an output matching network coupled to an output of the at least one power amplifier, the output matching network including a switch on a semiconductor-on-insulator die, and the compound semiconductor die and the semiconductor on insulator die being on a common substrate and packaged together with each other; and a bias circuit configured to provide a reference current with a first reference current level to the at least one power amplifier in the first mode and a second reference current level to the at least one power amplifier in the second mode, the multi-mode power amplifier system configured to adjust a power amplifier signal path for the second mode relative to the first mode.

In other embodiments, the compound semiconductor die is a silicon germanium die and the semiconductor-on-insulator die is a silicon-on-insulator die. In another embodiment, the at least one power amplifier is configured to adjust a power amplifier signal path by adjusting an output matching impedance of the output matching network. In a further embodiment, the output matching network includes a switch configured to include a capacitor in the output matching impedance in the first mode and to not include the capacitor in the output matching impedance in the second mode.

In various embodiments, a wireless communication device with a multi-mode power amplifier system comprises: a multi-mode power amplifier system including at least one power amplifier configured to amplify a radio frequency signal in at least a first mode and a second mode, an output matching network coupled to an output of the at least one power amplifier, and a bias circuit configured to provide a reference current with a first reference current level to the at least one power amplifier in the first mode and a second reference current level to the at least one power amplifier in the second mode, the multi-mode power amplifier system configured to adjust a power amplifier signal path for the second mode relative to the first mode; and an antenna operatively coupled to the at least one power amplifier by way of at least the output matching network in both the first and second modes of operation. In other embodiments, the multi-mode power amplifier system includes a baseband processor configured to provide a mode select signal to the bias circuit.

In certain embodiments, the present disclosure relates to methods of operating a multi-mode power amplifier system. In one embodiment, a method of operating a multi-mode power amplifier system comprises: amplifying a radio frequency signal in a first mode with at least one power amplifier; adjusting a power amplifier signal path and a reference current level for the at least one power amplifier; and after said adjusting, amplifying the radio frequency signal in a second mode with the at least one power amplifier, the reference current level and the power amplifier signal path both being different for the second mode than the first mode.

In various emboidiments, a multi-mode power amplifier system comprises: at least one power amplifier having at least a first mode and a second mode, the at least one power amplifier configured to amplify a radio frequency signal; and an output matching network including a first section and a second section coupled to an output of the at least one power amplifier by way of the first section, the second section including an inductor, a capacitor, and a switch; the switch configured to include the capacitor in an output matching impedance for the at least one power amplifier in the first mode and to not include the capacitor in the output matching impedance for the at least one power amplifier in the second mode.

In one or more embodiments, the first mode is a wireless local area network mode and the second mode is a wireless personal area mode. In another embodiment, the first mode is a Wi-Fi mode and the second mode is a Bluetooth mode.

In one embodiment, the inductor the multi-mode power amplifier system is a surface mount inductor. In another embodiment, the inductor is a series inductor and the capacitor is a shunt capacitor. In yet another embodiment, the inductor is a series inductor and the capacitor is a shunt capacitor.

In certain embodiments, the switch is on a semiconductor-on-insulator die. In another embodiment, a low noise amplifier is on the semiconductor-on-insulator die. In an additional embodiment, the at least one power amplifier is on a compound semiconductor die. In a further embodiment, the compound semiconductor die is a silicon germanium die, and the semiconductor-on-insulator die is a silicon-on-insulator die.

In one or more embodiments, the multi-mode power amplifier system further comprises a bias circuit, the at least one power amplifier including a main power amplifier transistor and an auxiliary power amplifier transistor, the bias circuit configured to bias the at least one power amplifier such that (i) the main power amplifier transistor and the auxiliary power amplifier transistor are on in the first mode and (ii) the main power amplifier transistor is on and the auxiliary power amplifier transistor is off in the second mode.

In another embodiment, the bias circuit is configured to provide a reference current to the at least one power amplifier, the reference current being different in the first mode than the second mode. In a further embodiment, the bias circuit is configured to provide a reference current to the at least one power amplifier, the reference current being different in the first mode than the second mode.

In various embodiments, multi-chip module with a multi-mode power amplifier system comprises: at least one power amplifier on a compound semiconductor die, the at least one power amplifier having at least a first mode and a second mode; and an output matching network including a first section and a second section coupled to an output of the at least one power amplifier by way of the first section, the second section including an inductor, a capacitor, and a switch, the switch being on a semiconductor-on-insulator die that is a same substrate as the compound semiconductor die, and the switch configured to include the capacitor in an output matching impedance for the at least one power amplifier in the first mode and to not include the capacitor in the output matching impedance for the at least one power amplifier in the second mode.

In one or more embodiments, the compound semiconductor die is a silicon germanium die and the semiconductor-on-insulator die is a silicon-on-insulator die. In another embodiment, the inductor is a surface mount inductor. In a further embodiment, the inductor is a series inductor and the capacitor is a shunt capacitor.

In various embodiments, a wireless communication device with a multi-mode power amplifier system comprises: a multi-mode power amplifier system having at least one power amplifier with at least a first mode and a second mode, the at least one power amplifier configured to amplify a radio frequency signal; an output matching network including a first section and a second section coupled to an output of the at least one power amplifier by way of the first section, the second section including an inductor, a capacitor, and a switch; the switch configured to include the capacitor in an output matching impedance for the at least one power amplifier in the first mode and to not include the capacitor in the output matching impedance for the at least one power amplifier in the second mode; and an antenna operatively coupled to the at least one power amplifier by way of at least the output matching network in both the first and second modes of operation.

In another embodiment, the multi-mode power amplifier system includes a baseband processor configured to provide a mode select signal to the bias circuit.

In certain embodiments, the present disclosure relates to methods of operating a multi-mode power amplifier system. In one embodiment, the method of operating a multi-mode power amplifier system comprises: amplifying a radio frequency signal in a first mode with a power amplifier; switching out a capacitor from an output matching impedance for the power amplifier with a switch, the switch and the capacitor being included in a second section of an output matching network that is coupled to an output of the power amplifier by way of a first section of the output matching network; and after said switching out, amplifying the radio frequency signal in a second mode with the power amplifier, the output matching impedance being different for the second mode than for the first mode.

### BRIEF DESCRIPTION OF THE DRAWINGS

Embodiments of this disclosure will now be described, by way of non-limiting example, with reference to the accompanying drawings.

FIG. 1A is a schematic diagram of an example multi-mode power amplifier system according to an embodiment. FIG. 1B is a table of signal values for the multi-mode power amplifier system of FIG. 1A for two modes of operation according to an embodiment. FIG. 1C is a table of signal values for the multi-mode power amplifier system of FIG. 1A for six modes of operation according to an embodiment.

FIG. 2A is a schematic diagram of part of an example multi-mode power amplifier system according to an embodiment. FIG. 2B is part of a Smith chart for sweeps of load line impedances of the multi-mode power amplifier system of FIG. 2A for two modes of operation.

FIGS. 3, 4 and 5 are schematic diagrams of example multi-mode power amplifier system according to embodiments.

FIGS. 6 and 7 are schematic block diagrams of an example multi-chip modules that include a multi-mode power amplifier system according to embodiments.

FIG. 8 is a schematic diagram of one embodiment of a mobile device.

FIG. 9 is a schematic diagram of a power amplifier system according to one embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Industry demands for a reduced power amplifier (PA) footprint can introduce significant challenges for front end module (FEM) suppliers, particularly to maintain high levels of PA performance in a reduced FEM size. Wireless Local Area Network (WLAN) and Bluetooth standards share overlapping frequency bands at or around 2.45 GHz, but have different PA power and linearity specifications. Attempts have been made to use a single PA chain for Wi-Fi and Bluetooth. However, significant performance degradation was introduced in comparison to utilizing a larger dual PA solution where one PA is implemented for Wi-Fi and another PA is implemented for Bluetooth.

This disclosure provides technical solutions where high performance is maintained in a single multi-mode PA chain. Radio frequency (RF) performance can be preserved relative to a significantly larger dual PA equivalent. The multi-mode PA chain can be a dual mode PA chain. The multi-mode PA chain can support the Bluetooth and Wi-Fi standards. Technical solutions disclosed herein involve reconfiguring the PA for different modes and using a split output matching network (OMN). These features can be implemented together with enhanced and/or optimized device sizing and enhanced and/or optimized load line impedance with relatively minimal matching losses. With such technical solutions, two PA modes can achieve higher performance comparable to a dual PA equivalent. At the same time, single dual-mode PA chains disclosed herein can achieve a greater than 50% chip size and cost reduction relative to dual PA equivalents.

RF systems with stringent technical specifications have typically used separate Bluetooth and Wi-Fi power amplifiers. An identical PA chain for both Wi-Fi and Bluetooth modes has been utilized and exploited dual registers to store independent reference current settings that provide independently optimized bias settings in both modes. However, as such solution uses an identical PA chain in both modes, the lower power Bluetooth mode can exhibit high current consumption, as the PA is oversized relative to its specification.

To achieve performance similar to separate Wi-Fi and Bluetooth PA solutions, this disclosure provides technical solutions that can use registers to enhance and/or optimize bias settings in a plurality of modes and also include addition features to preserve high performance and to meet technical specifications in each of the modes.

Auxiliary (AUX) power amplifier transistor shutdown, or device de-biasing, in a PA output stage can be implemented to effectively resize the PA devices. This can allow accurate control of the output power and current consumption of the PA, specific to the standard of operation for the PA.

A split OMN architecture can be implemented that incorporates load line switching via a switched capacitor. The switch and the capacitor can be on a silicon-on-insulator (SOI) die. Switching can introduce output matching network loss that can degrade performance. In certain applications, a single switch can be used to mitigate the impact of switching on output matching network loss. Including the switch at the load end of the OMN together with a surface mount technology (SMT) series inductor can allow a relatively large range of Wi-Fi load line control around the Smith Chart with a relatively minor impact on the real part of the Bluetooth load line impedance. The switching capacitor being at or near an antenna port can allow an impedance trajectory that moves from a highly inductive Bluetooth load line (e.g., due to parasitic off-state AUX devices) towards a real but lower load line in Wi-Fi mode. The Bluetooth load line impedance can be tuned or set with a first OMN section and a second OMN section can be used to tune or set the Wi-Fi mode load line impedance.

Gain in a plurality of modes can be controlled by gain stage periphery switching and/or power amplifier transistor deactivation. For higher gain, auxiliary power amplifier transistors can be included in the gain stage. In a lower power mode with lower gain, a portion of the gain stage can be shut down to meet a desired lower gain operation. This can involve deactivating the auxiliary power amplifier transistor of the gain stage.

Technology described herein can achieve reduced current consumption in a Bluetooth mode by approximately 80% relative to designs that adjust reference current between modes and otherwise include the same power amplifier signal path for Bluetooth and Wi-Fi modes. For Bluetooth applications, current consumption is a significant technical specification. Optimized and/or enhanced device sizing, load lines, and reference current control (e.g., via registers) for a plurality of modes, can achieve tight gain control over temperature, increased linearity, reduced out of band emissions (OOBE), or any suitable combination thereof. Tuning with a split OMN architecture can contribute to quicker time to market in comparison to tuning a non-partitioned OMN. Architectures disclosed herein can achieve high performance for both Bluetooth and Wi-Fi in a small footprint.

Multi-mode power amplifier system embodiments will be now be discussed with reference to the figures.

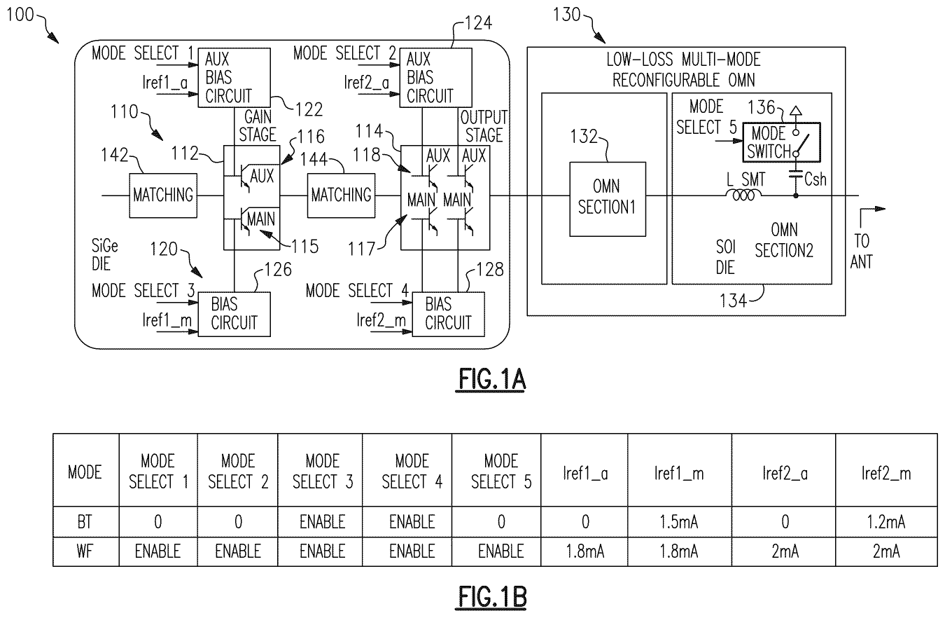

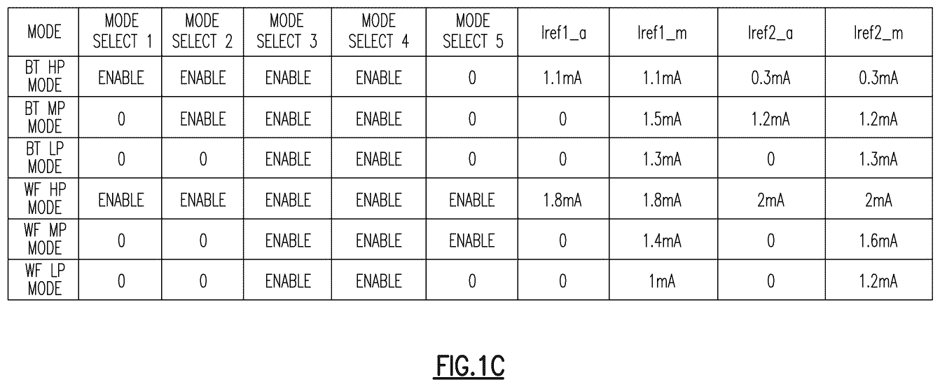

FIG. 1A is a schematic diagram of an example multi-mode power amplifier system 100 according to an embodiment. As illustrated, the multi-mode power amplifier system 100 includes a power amplifier 110, a bias circuit 120, and an output matching network 130. For different modes of operation, the multi-mode power amplifier system 100 can adjust reference current for the power amplifier 110, selectively activate or deactivate one or more auxiliary power amplifier transistors, adjust an output matching impedance for the power amplifier 110, or any suitable combination thereof.

The multi-mode power amplifier system 100 can operate in at least two modes. For example, the multi-mode power amplifier system 100 can operate in 2 modes corresponding to FIG. 1B. As another example, the multi-mode power amplifier system 100 can operate in 6 modes corresponding to FIG. 1C. The at least 2 modes can relate to different radio access technologies. The at least 2 modes can include a WLAN mode and a wireless personal area network (WPAN) mode. For instance, the WLAN mode can be a Wi-Fi mode and the WPAN mode can be a Bluetooth mode. The at least two modes can be different power modes, such as one or more of low power (LP), medium power (MP), or high power (HP). The at least two modes can include modes that are a combination of a standard for wireless communication and power level. For instance, the modes can include a Wi-Fi LP mode, a Wi-Fi MP mode, a Wi-Fi HP mode, a Bluetooth LP mode, a Bluetooth MP mode, and a Bluetooth HP. The at least two modes can include modes associated with different linearity specifications, coexistence and non-coexistence modes, the like, or any suitable combination thereof.

An input matching network 142 and an interstage matching network 144 can be included for the power amplifier 110. The illustrated power amplifier 110 includes a gain stage 112 and an output stage 114. In some other applications, a power amplifier in accordance with any suitable principles and advantages disclosed herein can include three or more stages.

The gain stage 112 can set or impact the gain of the power amplifier 110. The gain stage 112 can include a main power amplifier transistor 115 and an auxiliary power amplifier transistor 116. The main power amplifier transistor 115 and/or the auxiliary power amplifier transistor 116 can be implemented by transistor arrays. These transistors can be silicon germanium transistors, for example. The main power amplifier transistor 115 and the auxiliary power amplifier transistor 116 of the gain stage 112 can have any suitable ratio relative to each other for a particular application.

The output stage 114 can include a main power amplifier transistor 117 and an auxiliary power amplifier transistor 118. The main power amplifier transistor 117 and/or the auxiliary power amplifier transistor 118 can each be implemented by transistor arrays. These transistors can be silicon germanium transistors, for example. The main power amplifier transistor 117 and the auxiliary power amplifier transistor of the output stage can have any suitable ratio relative to each other for a particular application 118. The transistors of the output stage 114 can be larger than the transistor of the gain stage 112.

The bias circuit 120 can a provide reference current to power amplifier transistors 115, 116, 117, and 118. The references currents can be different for the gain stage 112 and the output stage 114 during the same mode of operation. The bias circuit 120 can include memory elements that store values for reference current settings that provide bias settings for each mode. The memory elements can include registers. Alternatively or additionally, the memory elements can include fuses. The settings stored in the memory elements of the bias circuit 120 can account for a power mode and a temperature profile of the power amplifier 110, for example. The bias circuit 120 can include bias circuitry 122, 124, 126, and 128 for individual PA transistors or transistor arrays.

The bias circuit 120 can select a mode of operation. The bias circuit 120 can disable the auxiliary power amplifier transistor 116 of the gain stage 112 based on a value of a mode select signal Mode Select 1 provided to the bias circuit 120. Alternatively or additionally, the bias circuit 120 can disable the auxiliary power amplifier transistor 118 of the output stage 114 based on a value of a mode select signal Mode Select 2 provided to the bias circuit 120.

The output matching network 130 is connected to an output of the power amplifier 110. The output matching network 130 can include a first section 132 and a second section 134 that is connected to the output of the power amplifier 110 by way of the first section 132. The first section 132 can be tuned for performance in one mode of operation. Passive impedance elements of the first section 132 can have respective impedance values that together provide impedance matching for the one mode of operation. The first section 132 can include passive impedance elements, such as one or more capacitors and one or more inductors, arranged in any suitable circuit topology and having any suitable impedance values for a particular application.

The second section 134 can adjust an output matching impedance for the power amplifier 110 for different modes of operation. As illustrated in FIG. 1A, the second section 134 includes a series SMT inductor L SMT and a shunt capacitor Csh in series with a switch 136. The switch 136 can switch in the capacitor Csh in the first mode and switch out the capacitor Csh in the second mode such that the impedance of the capacitor Csh is included in the output matching impedance in the first mode and not in the second mode. By adjusting the output matching impedance, the second section 134 can tune the output impedance for a mode of operation. For example, the first section 132 can tune output matching impedance for a Bluetooth mode and the second section 134 can tune output matching impedance for a Wi-Fi mode. A load line impedance can be referred to as an output matching impedance.

The power amplifier 110 can be on a silicon germanium die. The bias circuit 120 can also be on the silicon germanium die. The switch 136 can be on a semiconductor-on-insulator die, such as a SOI die. The capacitor Csh can also be on the SOI die. The first section 132 of the OMN 130 can include one or more SMT passive impedance elements. The first section 132 of the OMN 130 can alternatively or additionally include one or more passive impedance elements on the silicon germanium die, one or more passive impedance elements on the SOI die, or one or more passive impedance elements on the silicon germanium die and one or more passive impedance elements on the SOI die.

FIG. 1B is a table of signal values for the multi-mode power amplifier system 100 of FIG. 1A for two modes of operation according to an embodiment. FIG. 1B will be discussed with reference to the multi-mode power amplifier system 100 of FIG. 1A for illustrative purposes. Any suitable principles and advantages discussed with reference to FIG. 1B can be implemented in any other suitable power amplifier system. The two modes are a Wi-Fi mode and a Bluetooth mode in FIG. 1B. The auxiliary power amplifier transistors 116 and 118 can be deactivated and reference currents can be reduced for the Bluetooth mode relative to the Wi-Fi mode. The output matching impedance for the power amplifier 110 can be adjusted by switching out the capacitor Csh for the Bluetooth mode and switched in the capacitor Csh for the Wi-Fi mode.

In a Wi-Fi mode, mode select signals Mode Select 1 to Mode Select 4 can enable the main power amplifier transistor 115 and the auxiliary power amplifier transistor 116 of the gain stage 112 and also enable the main power amplifier transistor 117 and the auxiliary power amplifier transistor 118 of the output stage 114. A mode select signal Mode Select 5 can turn on the switch 136 of the OMN 130 to switch in the capacitor Csh for the Wi-Fi mode.

In a Bluetooth mode, the mode select signals Mode Select 1 to Mode Select 4 can enable the main power amplifier transistor 115 of the gain stage 112 and the main power amplifier transistor 117 of the output stage 114 while disabling the auxiliary power amplifier transistor 116 of the gain stage 112 and the auxiliary power amplifier transistor 118 of the output stage 114. The bias circuit 120 (e.g., bias circuitry 126 and 128) can reduce the reference currents Iref1_m and Iref2_m for respective main power amplifier transistors 115 and 117 for the Bluetooth mode relative to the Wi-Fi mode. FIG. 1B provides example reductions in reference current values. The bias circuit 120 (e.g., bias circuitry 122 and 124) can reduce the reference currents Iref1_a and Iref2_a to zero or approximately zero for the auxiliary power amplifier transistors 116 and 118 for the Bluetooth mode. A mode select signal Mode Select 5 can turn off the switch 136 of the OMN 130 to switch out the capacitor for the Bluetooth mode.

FIG. 1C is a table of signal values for the multi-mode power amplifier system 100 of FIG. 1A for six modes according to an embodiment. FIG. 1C will be discussed with reference to the multi-mode power amplifier system 100 of FIG. 1A for illustrative purposes. Any suitable principles and advantages discussed with reference to FIG. 1C can be implemented in any other suitable power amplifier system. The six modes are a LP Wi-Fi mode, a MP Wi-Fi mode, a HP Wi-Fi mode, a LP Bluetooth mode, a MP Bluetooth mode, and a HP Bluetooth mode in FIG. 1C.

The auxiliary power amplifier transistor 116 of the gain stage 112 can be activated for the Wi-Fi HP mode and the Bluetooth HP mode. This is indicated in FIG. 1C by the Mode Select 1 signal having an Enable value. The auxiliary power amplifier transistor 116 of the gain stage 112 can be deactivated for the other modes of FIG. 1C.

The auxiliary power amplifier transistor 118 of the output stage 114 can be activated for the Wi-Fi HP mode, the Bluetooth MP mode, and the Bluetooth HP mode. This is indicated in FIG. 1C by the Mode Select 2 signal having an Enable value. The auxiliary power amplifier transistor 118 of the output stage 114 can be deactivated for the other modes of FIG. 1C.

FIG. 1C provides example reference current values for the various modes. The reference current Iref1_a for the auxiliary power amplifier transistor 116 of the gain stage 112 can be zero or approximately zero when deactivated. The reference current Iref2_a for the auxiliary power amplifier transistor 118 of the output stage 114 can be zero or approximately zero when deactivated.

The capacitor Csh can be switched in for the output matching impedance for the Wi-Fi HP mode and the Wi-Fi MP modes. This is indicated in FIG. 1C by the Mode Select 5 signal having an Enable value. The capacitor Csh can be switched out and not included in the output matching impedance for the other modes of FIG. 1C.

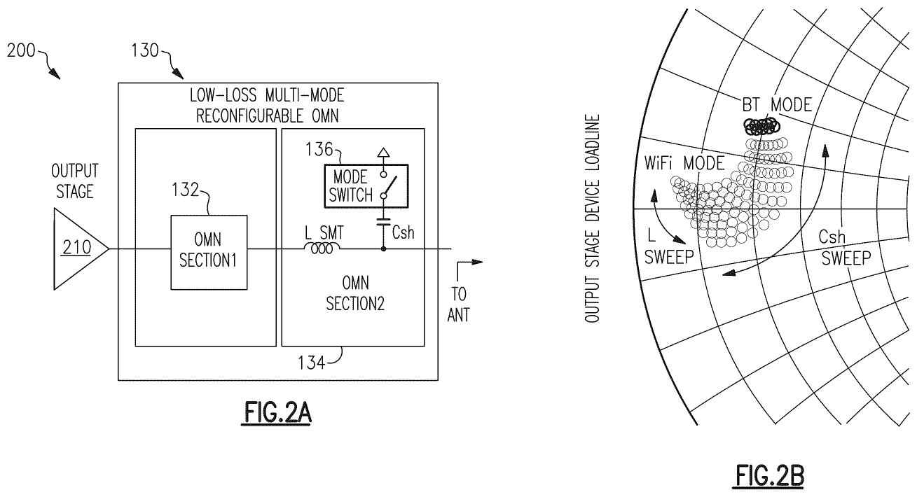

FIG. 2A is a schematic diagram of part of an example multi-mode power amplifier system 200 according to an embodiment. FIG. 2A illustrates a PA output stage 210 and an OMN 130. The output stage 210 can be any suitable power amplifier output stage. In certain applications, the output stage 210 can be implemented in accordance with any suitable principles and advantages discussed with reference to the output stage 114 of FIG. 1A. The OMN 130 has a split configuration that provides desirable control over the load line impedance in a plurality of modes. The first section 132 of the OMN 130 can be tuned for desirable and/or optimal Bluetooth performance. The second section 134 of the OMN 130 can provide an impedance tuner for Wi-Fi mode. The second section 134 of the OMN 130 includes a shunt capacitor Csh, a switch 136, and a series inductor L SMT. The switch 136 can be on the same die as a low noise amplifier. Such a die can be a SOI die. The shunt capacitor Csh can also be on the same die as the switch 136 and the low noise amplifier. The series inductor L SMT can be a SMT inductor. The second section 134 of the OMN 130 can provide a relatively large range of Wi-Fi tuning impedances for only a relatively small real part of the Bluetooth load line change. The series inductor L SMT being a surface mount inductor can contribute to achieving such features. Any relatively slight Bluetooth real (ZL) shift can be compensated for in the first section of the OMN.

FIG. 2B is part of a Smith chart for sweeps of load line impedances of the multi-mode power amplifier system 200 of FIG. 2A for two modes of operation. The two modes in FIG. 2B are a Wi-Fi mode and a Bluetooth mode. Load line impedances at the output device reference plane are shown when the inductance of the series inductor L SMT and the capacitance of the shunt capacitor Csh are swept for both modes. The Bluetooth mode load line impedance has a relatively small change for these sweeps. The Wi-Fi mode load line impedance can change within a relatively large range for these sweeps. FIG. 2B illustrates that the split OMN topology of FIG. 2A can implement impedance matching for Bluetooth mode with the first section 132 of the OMN 130 and that the inductance of the series inductor L SMT and the capacitance of the shunt capacitor Csh can be selected to tune the Wi-Fi load line impedance.

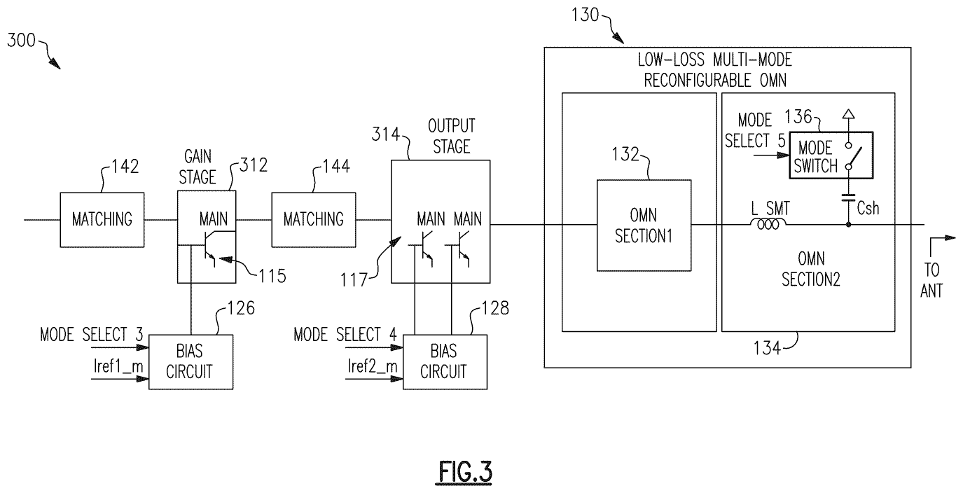

FIGS. 3, 4 and 5 are schematic diagrams of example multi-mode power amplifier system according to embodiments. These example multi-mode power amplifier systems can implement any suitable combination of features discussed above. In these multi-mode power amplifier systems, a bias circuit can adjust reference current for the power amplifier in different modes and also adjust a power amplifier signal path for the different modes. The power amplifier signal path can be referred to as a power amplifier signal chain. The power amplifier signal path can be adjusted by activating and/or deactivating one or more auxiliary power amplifier transistors. Alternatively or additionally, the power amplifier signal path can be adjusted by adjusting an output matching impedance for the power amplifier. Any suitable principles and advantages of these multi-mode power amplifier systems can be implemented together with each other.

FIG. 3 is a schematic diagram of an example multi-mode power amplifier system 300 with adjustable power amplifier reference currents and an adjustable output matching network according to an embodiment. The multi-mode power amplifier system 300 is like the multi-mode power amplifier system 100 of FIG. 1A, except that no auxiliary power amplifier transistors and corresponding biasing circuitry are implemented. The multi-mode power amplifier system 300 includes a gain stage 312 with main power amplifier transistor 115 and an output stage 314 with main power amplifier transistor 117. The gain stage 312 and the output stage 314 do not include auxiliary power amplifier transistors.

As one example, the multi-mode power amplifier system 300 can implement a Bluetooth HP mode and a Wi-Fi HP mode. These modes can use the same PA transistors (e.g., as shown by the same PA transistors being enabled by mode select signals for these modes in FIG. 1C) and can be implemented without resizing the power amplifier. The output matching impedance can be adjusted by enabling the switch 136 for the Wi-Fi HP mode and disabling the switch 136 for the Bluetooth HP mode.

In some other applications, a multi-mode power amplifier can include one or more stages with an auxiliary power amplifier transistor and one or more stages without an auxiliary power amplifier transistor. Such a multi-mode power amplifier can be implemented with a bias circuit that can provide an adjustable bias current and/or with an output matching network with an adjustable output matching impedance.

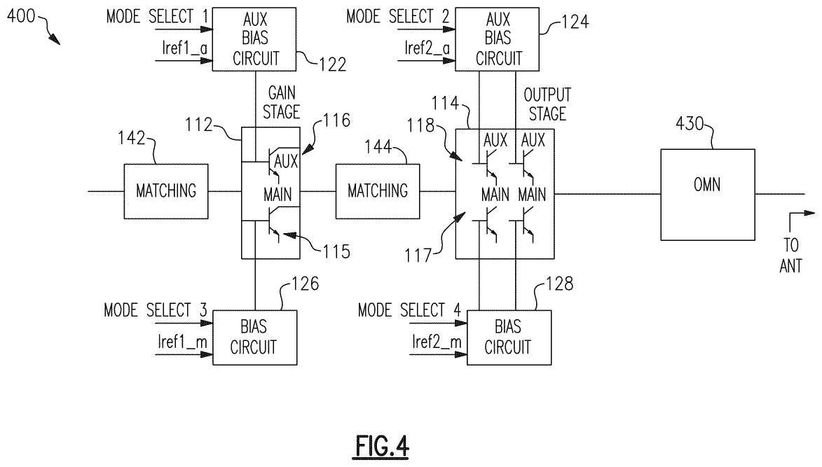

FIG. 4 is a schematic diagram of an example multi-mode power amplifier system 400 with adjustable power amplifier reference currents and auxiliary power amplifier transistors according to an embodiment. The multi-mode power amplifier system 400 is like the multi-mode power amplifier system 100 of FIG. 1A, except that the OMN 430 is not adjustable. The OMN 430 can be any suitable OMN that provides output matching for two or modes of operation of the multi-mode power amplifier system 400.

As one example, the multi-mode power amplifier system 400 can implement two or more of a Bluetooth HP mode, a Bluetooth MP mode, a Bluetooth LP mode, or a Wi-Fi LP mode. These modes can use the same output matching impedance (e.g., as shown by Mode Select 5 having a 0 value in FIG. 1C to turn off the switch 136 of FIG. 1A).

As another example, the multi-mode power amplifier system 30 can implement a Wi-Fi MP mode and a Wi-Fi LP mode. These modes can use the same output matching impedance (e.g., as shown by Mode Select 5 having an Enable value in FIG. 1C to activate the switch 136 of FIG. 1A).

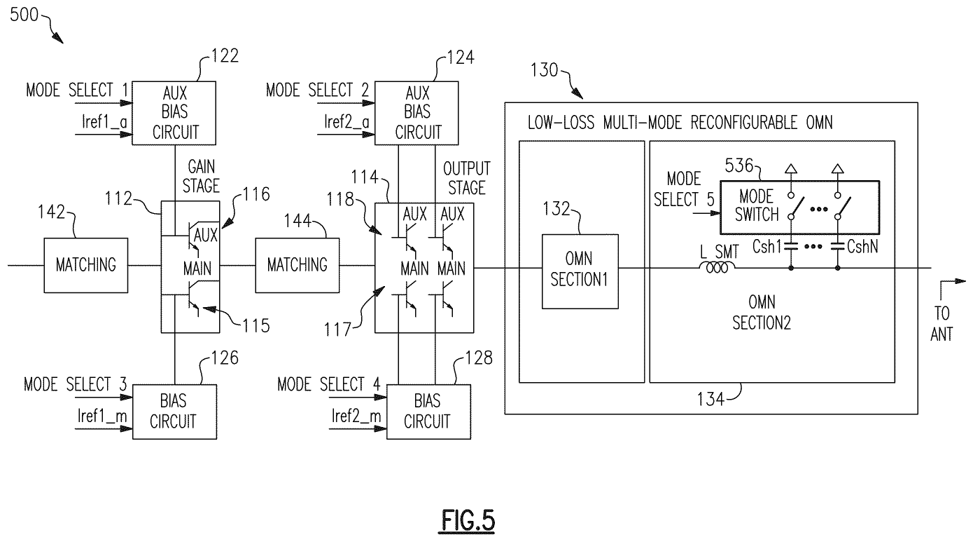

FIG. 5 is a schematic diagram of an example multi-mode power amplifier system 500 with adjustable output matching impedance according to an embodiment. The multi-mode power amplifier system 500 is like the multi-mode power amplifier system 100 of FIG. 1A, except that the multi-mode power amplifier system 500 includes an array of switches 536 and capacitors Csh1 to CshN instead of the switch 136 and the capacitor Csh. An array of switches 536 and capacitors Csh1 to CshN can provide more tunability of the output matching impedance than a single switch and single capacitor. Additional tunability post manufacture can advantageously allow for tuning for different applications post manufacture and/or account for process variations or other issues introduced during manufacture.

In different modes of operation, a different number of capacitors Csh1 to CshN can be included in the output matching impedance using the switches 536. For instance, in one mode of operation all of the capacitors Csh1 to CshN can be switched out of the output matching impedance and one or more of the capacitors Csh1 to CshN can be switched in for another mode of operation. Alternatively or additionally, some of the capacitors Csh1 to CshN can be switched in for a mode of operation and at least one different capacitor Csh1 to CshN can be switched in for another mode of operation.

Any other suitable circuit elements can be used to adjust the output matching impedance. One or more shunt capacitors, one or more series capacitors, one or more series inductors, one or more shunt inductors, or any suitable combination thereof can be used to adjust an output matching impedance for a power amplifier. Such circuit elements can be arranged in any suitable circuit topology for a particular application. One or more switches can be used to adjust the output matching impedance. In some instances, the output matching impedance can be adjusted without using a switch. For example, a voltage applied to a varactor can be adjusted to adjust the output matching impedance.

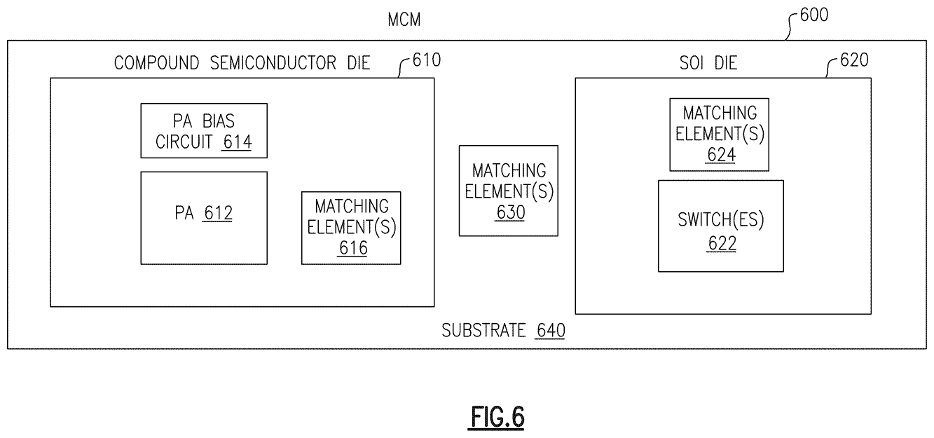

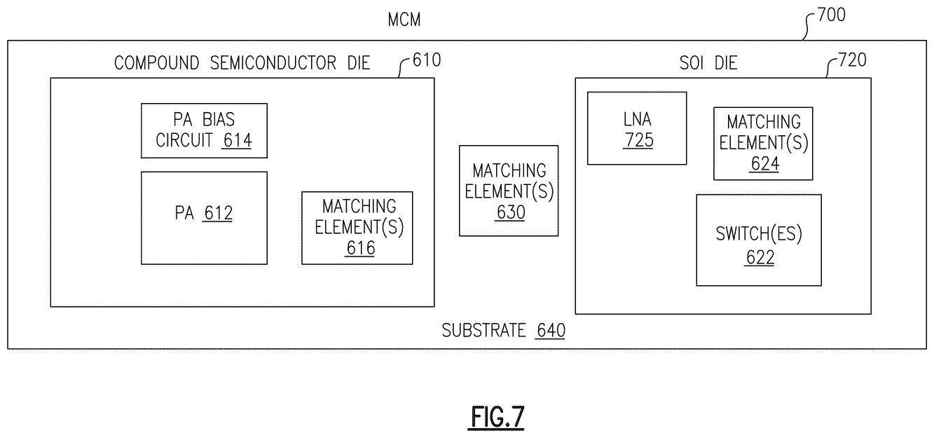

Multi-mode power amplifier systems disclosed here can be implemented on multi-chip modules. FIGS. 6 and 7 are schematic block diagrams of an example multi-chip modules that can include a multi-mode power amplifier system according to an embodiment. A multi-chip module can include a plurality of die on a common substrate. One or more additional components can be included on the substrate. A molding or encapsulation material can be included over the component(s) and die on the substrate. The multi-chip modules of FIGS. 6 and 7 can be referred to as packaged radio frequency modules and/or power amplifier modules.

FIG. 6 illustrates an example a multi-chip module 600. The multi-chip module 600 includes a compound semiconductor die 610, a SOI die 620, and matching element(s) 630 on a substrate 640. The compound semiconductor die 610 includes a power amplifier 612, a bias circuit 614, and one or more matching elements 616. The power amplifier 612 and the bias circuit 614 can be implemented in accordance with any suitable principles and advantages of the multi-mode power amplifier systems disclosed herein. The compound semiconductor die 610 can be a SiGe die. The one or more matching elements 616 can be included in a first section of an OMN of a multi-mode power amplifier system.

The matching element(s) 630 can include one or more SMT capacitors, one or more SMT inductors, one or more trace inductors, one or more wire bond inductors, or any suitable combination thereof. The first section of the OMN can include at least one of the matching element(s) 630 on the substrate 640. A second section of the OMN can include at least one of the matching element(s) 630 on the substrate 640. For example, the matching element(s) 630 can include a series SMT inductor of the second section of the OMN. The substrate 640 can be a laminate substrate.

The SOI die 620 can include switch(es) 622 and matching element(s) 624. SOI switches can provide relatively high isolation, relatively low loss, one or more other desirable technical features for switches, or any suitable combination thereof. The switch(es) 622 can include a switch of the second section of the OMN to adjust output matching impedance for the power amplifier 612. The switch(es) 622 can include one or more switches in a PA signal path, such as one or more band select switches, one or more transmit/receive switches, one or more antenna switches, or any suitable combination thereof. The matching element(s) 624 can include one or more capacitors and/or one or more inductors implemented on the SOI die 620. The matching element(s) 624 can include one or more passive impedance elements of the second section of the OMN. For example, the matching element(s) 624 can include a shunt capacitor connected to a switch of the switch(es) 622 that can be implemented in accordance with any suitable principles and advantages of the multi-mode power amplifier systems disclosed herein. The matching element(s) 624 can include one or more passive impedance elements of the first section of the OMN.

FIG. 7 illustrates another example a multi-chip module 700. The multi-chip module 700 is like the multi-chip module 600 of FIG. 6, except that the SOI die 720 of the multi-chip module of FIG. 7 also includes a low noise amplifier 725. The low noise amplifier 725 can be in a receive path. The receive path can be coupled to the same antenna switch as a power amplifier path that includes the power amplifier 612 and associated OMN.

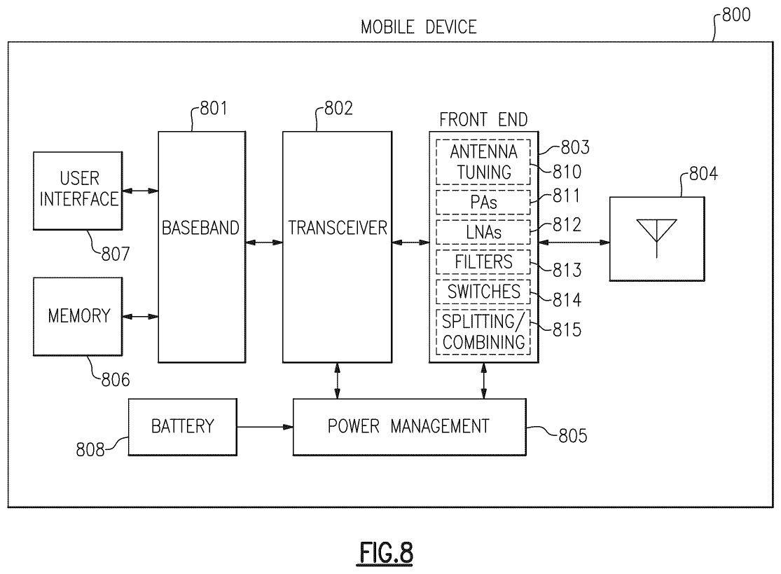

FIG. 8 is a schematic diagram of one embodiment of a mobile device 800. The mobile device 800 can include a multi-mode power amplifier system in accordance with any suitable principles and advantages disclosed herein. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 8 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAs) 811, low noise amplifiers (LNAs) 812, filters 813, switches 814, and signal splitting/combining circuitry 815. However, other implementations are possible. Any suitable principles and advantages of the multi-mode power amplifiers disclosed herein can be implemented in the PAs 811. The PAs 811 can include a multi-mode PA for Wi-Fi and Bluetooth and one or more other PAs for cellular communications.

For example, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 8, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 8, the power management system 805 receives a battery voltage from the battery 808. The battery 808 can be any suitable battery for use in the mobile device 800, including, for example, a lithium-ion battery.

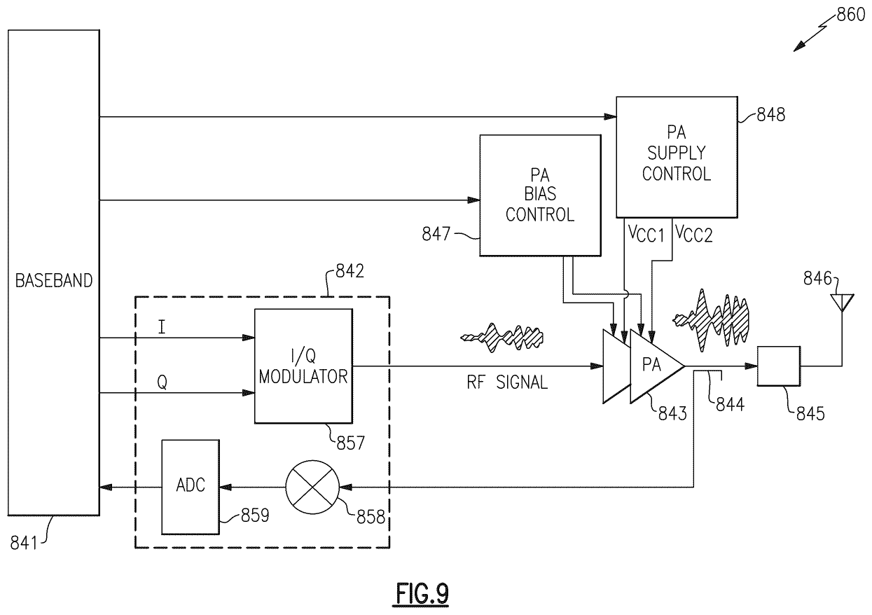

FIG. 9 is a schematic diagram of a power amplifier system 860 according to one embodiment. The power amplifier system 860 can have multiple modes of operation in accordance with any suitable principles and advantages disclosed herein. The illustrated power amplifier system 860 includes a baseband processor 841, a transmitter/observation receiver 842, a power amplifier (PA) 843, a directional coupler 844, front-end circuitry 845, an antenna 846, a PA bias control circuit 847, and a PA supply control circuit 848. The PA 843 can implement any suitable principles and advantages of the multi-mode PAs disclosed herein. The PA bias control circuit 847 can provide one or more mode control signals and/or one or more reference currents to the PA 843 in accordance with any suitable principles and advantages disclosed herein. The illustrated transmitter/observation receiver 842 includes an I/O modulator 857, a mixer 858, and an analog-to-digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/O modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 841 can be included in the power amplifier system 860.

The I/O modulator 857 can be configured to receive the I and Q signals from the baseband processor 841 and to process the I and Q signals to generate an RF signal. For example, the I/O modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the power amplifier 843. In certain implementations, the I/O modulator 857 can include one or more filters configured to filter frequency content of signals processed therein.

The power amplifier 843 can receive the RF signal from the I/O modulator 857, and when enabled can provide an amplified RF signal to the antenna 846 via the front-end circuitry 845.

The front-end circuitry 845 can be implemented in a wide variety of ways. In one example, the front-end circuitry 845 includes one or more switches, filters, duplexers, multiplexers, and/or other components. In another example, the front-end circuitry 845 is omitted in favor of the power amplifier 843 providing the amplified RF signal directly to the antenna 846.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841. Including a feedback path from the output of the power amplifier 843 to the baseband processor 841 can provide a number of advantages. For example, implementing the baseband processor 841 in this manner can aid in providing power control, compensating for transmitter impairments, and/or in performing digital pre-distortion (DPD). Although one example of a sensing path for a power amplifier is shown, other implementations are possible.

The PA supply control circuit 848 receives a power control signal from the baseband processor 841, and controls supply voltages of the power amplifier 843. In the illustrated configuration, the PA supply control circuit 848 generates a first supply voltage V_{CC1} for powering an input stage of the power amplifier 843 and a second supply voltage V_{CC2} for powering an output stage of the power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation.

One technique for improving efficiency of a power amplifier is average power tracking (APT), in which a DC-to-DC converter is used to generate a supply voltage for a power amplifier based on the power amplifier's average output power. Another technique for improving efficiency of a power amplifier is envelope tracking (ET), in which a supply voltage of the power amplifier is controlled in relation to the envelope of the RF signal. Thus, when a voltage level of the envelope of the RF signal increases the voltage level of the power amplifier's supply voltage can be increased. Likewise, when the voltage level of the envelope of the RF signal decreases the voltage level of the power amplifier's supply voltage can be decreased to reduce power consumption.

In certain configurations, the PA supply control circuit 848 is a multi-mode supply control circuit that can operate in multiple supply control modes including an APT mode and an ET mode. For example, the power control signal from the baseband processor 841 can instruct the PA supply control circuit 848 to operate in a particular supply control mode.

As shown in FIG. 9, the PA bias control circuit 847 receives a bias control signal from the baseband processor 841, and generates bias control signals for the power amplifier 843. In the illustrated configuration, the bias control circuit 847 generates bias control signals for both an input stage of the power amplifier 843 and an output stage of the power amplifier 843. However, other implementations are possible.

Any of the embodiments described above can be implemented in association with mobile devices such as cellular handsets. Some of the embodiments described above have provided examples in connection with mobile devices. However, the principles and advantages of the embodiments can be used for any other systems or apparatus that have needs for power amplifier systems. Examples of such RF communication systems and apparatus include, but are not limited to, uplink wireless communications devices, mobile phones, tablets, base stations, network access points, customer-premises equipment (CPE), laptops, and wearable electronics.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a hand-held computer, a laptop computer, a tablet computer, a home appliance, a vehicular electronics system such as an automotive electronics system, a robot such as an industrial robot, an Internet of things device, etc. Further, the electronic devices can include unfinished products.

Any of the principles and advantages discussed herein can be implemented in association with RF circuits configured to amplify and process signals having a frequency in a range from about 30 kHz to 300 GHz, such as in a frequency range from about 400 MHz to 8.5 GHz. Such radio frequency signals can include wireless local area network signals and/or wireless personal area network signals. Power amplifier systems disclosed herein can generate RF signals at frequencies within Frequency Range 1 (FR1) of a fifth generation (5G) New Radio (NR) specification.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description is not intended to be exhaustive or to limit the embodiments of the disclosure to the precise form disclosed above. While specific embodiments and examples are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the system described above. The elements and acts of the various embodiments described above can be combined to provide further embodiments.

While certain embodiments have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A multi-mode power amplifier system comprising:
a power amplifier including a first power amplifier transistor and a second power amplifier transistor, the power amplifier configured to amplify a radio frequency signal;
a bias circuit configured to bias the power amplifier such that (i) the first power amplifier transistor and the second power amplifier transistor are on in a first mode and (ii) the first power amplifier transistor is on and the second power amplifier transistor is off in a second mode; and
an output matching network coupled to an output of the power amplifier, the output matching network configured to adjust an output matching impedance for the power amplifier for the second mode relative to the first mode.

2. The multi-mode power amplifier system of claim 1 wherein the first mode is a wireless local area network mode and the second mode is a wireless personal area network mode.

3. The multi-mode power amplifier system of claim 1 wherein the first mode a Wi-Fi mode and the second mode is a Bluetooth mode.

4. The multi-mode power amplifier system of claim 1 wherein the output matching network includes a switch configured to adjust the output matching impedance for the power amplifier for the second mode relative to the first mode.

5. The multi-mode power amplifier system of claim 4 wherein the switch is configured to include a capacitor in the output matching impedance in the first mode and to not include the capacitor in the output matching impedance in the second mode.

6. The multi-mode power amplifier system of claim 5 wherein the capacitor is a shunt capacitor and the output matching network includes a series inductor.

7. The multi-mode power amplifier system of claim 6 wherein the series inductor is a surface mount inductor.

8. The multi-mode power amplifier system of claim 6 wherein the output matching network includes a first section and a second section coupled to the output of the power amplifier by way of the first section, the second section including the switch, the series inductor, and the shunt capacitor.

9. The multi-mode power amplifier system of claim 4 wherein the power amplifier is on a silicon germanium die and the switch is on a silicon-on-insulator die.

10. The multi-mode power amplifier system of claim 1 wherein the power amplifier includes a gain stage and an output stage, the output stage including the first power amplifier transistor and the second power amplifier transistor.

11. The multi-mode power amplifier system of claim 10 wherein the gain stage includes a third power amplifier transistor and a fourth power amplifier transistor, and the bias circuit is configured to bias the gain stage such that (i) the third power amplifier transistor and the fourth power amplifier transistor are on in the first mode and (ii) the third power amplifier transistor is on and the fourth power amplifier transistor is off in the second mode.

12. The multi-mode power amplifier system of claim 1 wherein the bias circuit is configured to provide a reference current to the first power amplifier transistor, the reference current being different in the first mode than in the second mode.

13. The multi-mode power amplifier system of claim 12 wherein the bias circuit includes memory elements that store reference current settings for at least the first mode and the second mode.

14. A multi-chip module with a multi-mode power amplifier system, the multi-chip module comprising:
a power amplifier on a compound semiconductor die, the power amplifier including a first power amplifier transistor and a second power amplifier transistor;
a bias circuit on the compound semiconductor die, the bias circuit configured to bias the power amplifier such that (i) the first power amplifier transistor and the second power amplifier transistor are on in a first mode and (ii) the first power amplifier transistor is on and the second power amplifier transistor is off in the second mode; and
an output matching network implemented at least partly on a semiconductor-on-insulator die, the output matching network configured to adjust an output matching impedance for the power amplifier for the second mode relative to the first mode, and the compound semiconductor die and the semiconductor-on-insulator die being on a common substrate and packaged together with each other.

15. The multi-chip module of claim 14 wherein the compound semiconductor die is a silicon germanium die and the semiconductor-on-insulator die is a silicon-on-insulator die.

16. The multi-chip module of claim 14 wherein the output matching network includes a switch configured to adjust the output matching impedance for the power amplifier for the second mode relative to the first mode.

17. The multi-chip module of claim 16 wherein the switch is configured to include a capacitor in the output matching impedance in the first mode and to not include the capacitor in the output matching impedance in the second mode.

18. A wireless communication device with a multi-mode power amplifier system, the wireless communication device comprising:
a multi-mode power amplifier system including a power amplifier with a first power amplifier transistor and a second power amplifier transistor, the power amplifier configured to amplify a radio frequency signal, a bias circuit configured to bias the power amplifier such that (i) the first power amplifier transistor and the second power amplifier transistor are on in a first mode and (ii) the first power amplifier transistor is on and the second power amplifier transistor is off in a second mode, and an output matching network coupled to an output of the power amplifier, the output matching network configured to adjust an output matching impedance for the power amplifier for the second mode relative to the first mode; and
an antenna operatively coupled to the power amplifier by way of at least the output matching network in both the first and second modes of operation.

19. The wireless communication device of claim 17 wherein the multi-mode power amplifier system includes a baseband processor configured to provide a mode select signal to the bias circuit.

20. A method of operating a multi-mode power amplifier system, the method comprising:
amplifying a radio frequency signal in a first mode with a first power amplifier transistor of a power amplifier and a second power amplifier transistor of the power amplifier;
adjusting a power amplifier signal path by deactivating the second power amplifier transistor and adjusting an output matching impedance for the power amplifier; and
after said adjusting, amplifying the radio frequency signal in a second mode with the first power amplifier transistor while the second power amplifier transistor is deactivated, the output matching impedance being different for the second mode than for the first mode.
